(19) United States
(12) Patent Application Publication
(10) Pub. No.: US 2025/0393341 A1
(43) Pub. Date: Dec. 25, 2025

(54) METHOD OF MANUFACTURING LIGHT EMITTING DEVICE

(71) Applicant: NICHIA CORPORATION, Anan-shi (JP)

(72) Inventor: Yasunobu HOSOKAWA, Tokushima-shi (JP)

(73) Assignee: NICHIA CORPORATION, Anan-shi (JP)

(21) Appl. No.: 19/233,153

(22) Filed: Jun. 10, 2025

(30) Foreign Application Priority Data
Jun. 21, 2024 (JP) 2024-100493

(51) Int. Cl. H10H 20/01; H01L 25/075

(52) U.S. Cl. CPC H10H 20/0364; H01L 25/0753; H10H 20/016; H10H 20/019; H10H 20/0361

(57) ABSTRACT

A method of manufacturing a light emitting device includes: providing a structure including: a first substrate, a plurality of light emitting parts arranged apart from one another on an upper surface of the first substrate, a metal layer disposed on an upper surface side of the first substrate and covering at least the light emitting parts, and a protective member covering the metal layer; bonding a second substrate to the protective member; exposing the lower surfaces of the light emitting parts by removing the first substrate; bonding a light transmissive member to the lower surfaces of the light emitting parts via a bonding member; removing the second substrate; creating exposed portions of the light transmissive member; removing the metal layer; and dividing the light transmissive member into individual pieces at the exposed portions.

### CROSS REFERENCE TO RELATED APPLICATION

This application claims priority to Japanese Patent Applications No. 2024-100493, filed on Jun. 21, 2024, the entire contents of which are hereby incorporated by reference.

### BACKGROUND

The present disclosure relates to a method of manufacturing a light emitting device.

Japanese Patent Publication No. 2016-149389 proposes a light emitting device in which a structure having a plurality of light emitting parts disposed therein and a light transmissive member are bonded via a bonding member. Such a method of manufacturing a light emitting device makes the light transmissive member prone to splitting failures if the bonding member is disposed at the splitting positions of the light transmissive member.

### SUMMARY

An object of an embodiment of the present invention is to provide a method of manufacturing a light emitting device capable of reducing splitting failures.

A method of manufacturing a light emitting device according to one embodiment of the present invention comprises providing a structure including a first substrate, a plurality of light emitting parts arranged apart from one another on an upper surface of the first substrate, a metal layer disposed on an upper surface side of the first substrate and covering at least the light emitting parts, and a protective member covering the metal layer; bonding a second substrate onto the protective member; exposing the lower surfaces of the light emitting parts by removing the first substrate; bonding a light transmissive member to the lower surfaces of the light emitting parts via a bonding member; removing the second substrate; creating exposed portions of the light transmissive member exposed from the bonding member by removing portions of the bonding member, each located between adjacent ones of the light emitting parts, and the protective member using the metal layer as a mask; removing the metal layer; and dividing the light transmissive member into individual pieces by splitting the light transmissive member at the exposed portions.

According to one embodiment of the present invention, a method of manufacturing a light emitting device capable of reducing splitting failures can be provided.

### BRIEF DESCRIPTION OF THE DRAWINGS

FIG. 1 is a plan view showing a first step of a method of manufacturing a light emitting device according to one embodiment.

FIG. 2 is a cross-sectional view showing the first step of the method of manufacturing a light emitting device according to the embodiment.

FIG. 3 is a cross-sectional view showing the first step of the method of manufacturing a light emitting device according to the embodiment.

FIG. 4 is a cross-sectional view showing the first step of the method of manufacturing a light emitting device according to the embodiment.

FIG. 5 is a cross-sectional view showing a second step of the method of manufacturing a light emitting device according to the embodiment.

FIG. 6 is a cross-sectional view showing a third step of the method of manufacturing a light emitting device according to the embodiment.

FIG. 7 is a cross-sectional view showing the third step of the method of manufacturing a light emitting device according to the embodiment.

FIG. 8 is a cross-sectional view showing a fourth step of the method of manufacturing a light emitting device according to the embodiment.

FIG. 9 is a cross-sectional view showing the fourth step of the method of manufacturing a light emitting device according to the embodiment.

FIG. 10 is a plan view showing the fourth step of the method of manufacturing a light emitting device according to the embodiment.

FIG. 11 is a plan view showing the fourth step of the method of manufacturing a light emitting device according to the embodiment.

FIG. 12 is a cross-sectional view showing the fourth step of the method of manufacturing a light emitting device according to the embodiment.

FIG. 13 is a cross-sectional view showing a fifth step of the method of manufacturing a light emitting device according to the embodiment.

FIG. 14 is a cross-sectional view showing a sixth step of the method of manufacturing a light emitting device according to the embodiment.

FIG. 15 is a cross-sectional view showing the sixth step of the method of manufacturing a light emitting device according to the embodiment.

FIG. 16 is a cross-sectional view showing a seventh step of the method of manufacturing a light emitting device according to the embodiment.

FIG. 17 is a cross-sectional view showing an eighth step of the method of manufacturing a light emitting device according to the embodiment.

FIG. 18 is a cross-sectional view showing the eighth step of the method of manufacturing a light emitting device according to the embodiment.

FIG. 19 is a cross-sectional view showing the eighth step of the method of manufacturing a light emitting device according to the embodiment.

FIG. 20 is a cross-sectional view showing a light source according to an embodiment.

### DETAILED DESCRIPTION

Certain embodiments of the present invention will be described below with reference to the accompanying drawings.

The drawings are schematic or conceptual. As such, the relationship between the thickness and the width of each member, size ratio of the members, and the like are not necessarily the same as those of an actual product. The same member or part shown in multiple drawings might appear different in size or ratio depending on the drawing.

The same reference numerals are used for elements similar to those previously described in the present specification and shown in the drawings, and repeated detailed explanations are omitted as appropriate.

To make the description easily understood, an XYZ orthogonal coordinate system is used to explain the layout and constituents of members. The X axis, the Y axis, and the Z axis are orthogonal to each other. The directions in which the X axis, the Y axis, and the Z axis extend are designated as “X direction,” “Y direction,” and “Z direction,” respectively. To make the explanation easily understood, the Z direction pointed by the arrow is occasionally referred to as upward, and the opposite direction downward, but these directions are irrespective of the direction of gravity. A “plan view” refers to a view of an object from the upper side to the lower side.

### Method of Manufacturing Light Emitting Device

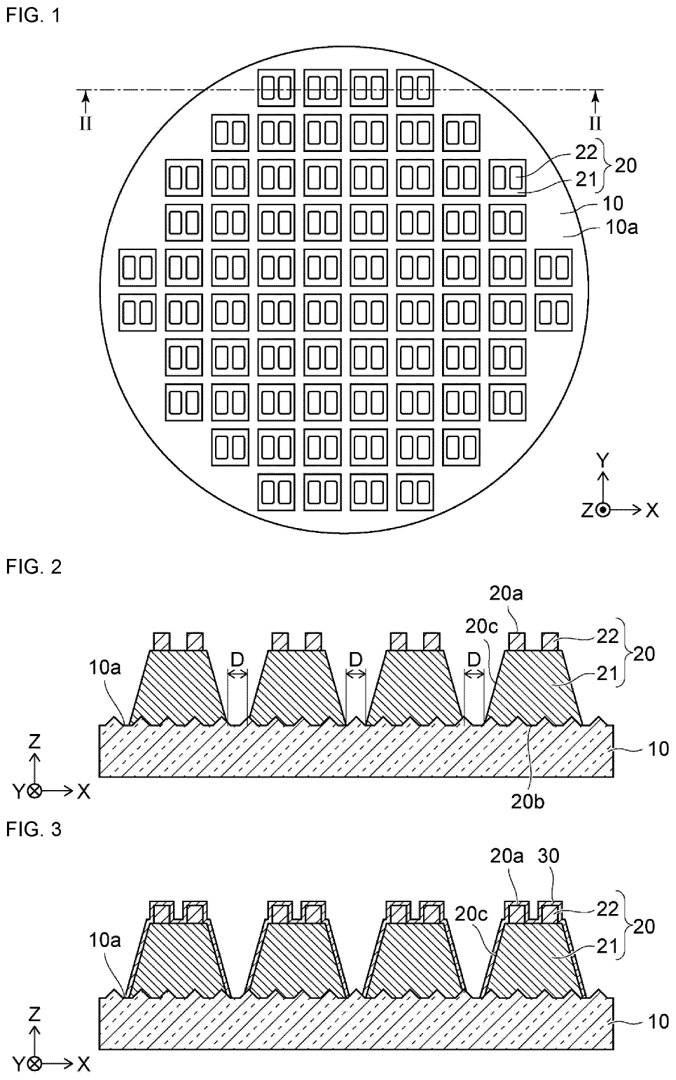

FIG. 1 is a plan view showing a first step of a method of manufacturing a light emitting device according to one embodiment.

FIG. 2 to FIG. 4 are cross-sectional views showing the first step of the method of manufacturing a light emitting device according to the embodiment.

FIG. 5 is a cross-sectional view showing a second step of the method of manufacturing a light emitting device according to the embodiment.

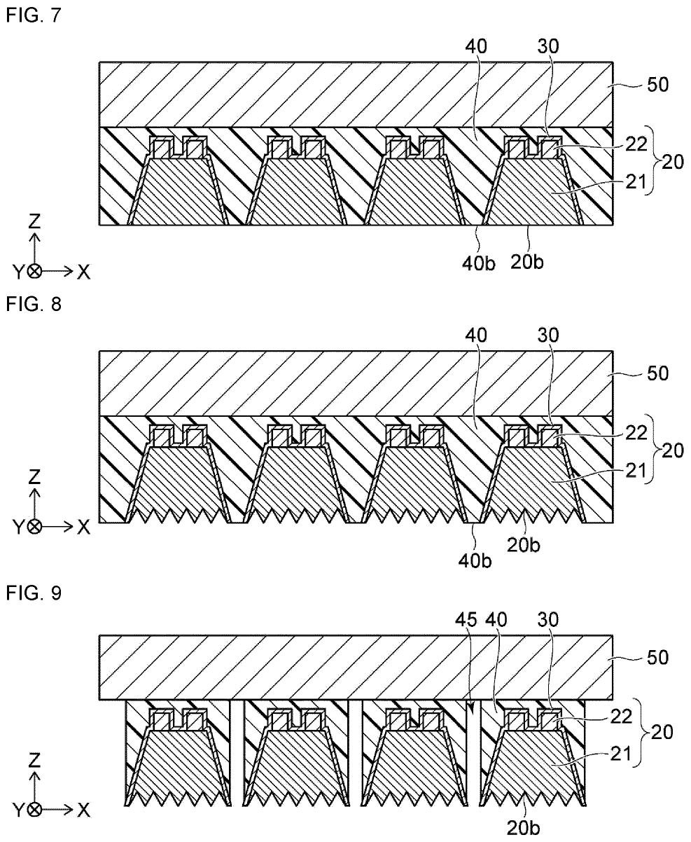

FIG. 6 and FIG. 7 are cross-sectional views showing a third step of the method of manufacturing a light emitting device according to the embodiment.

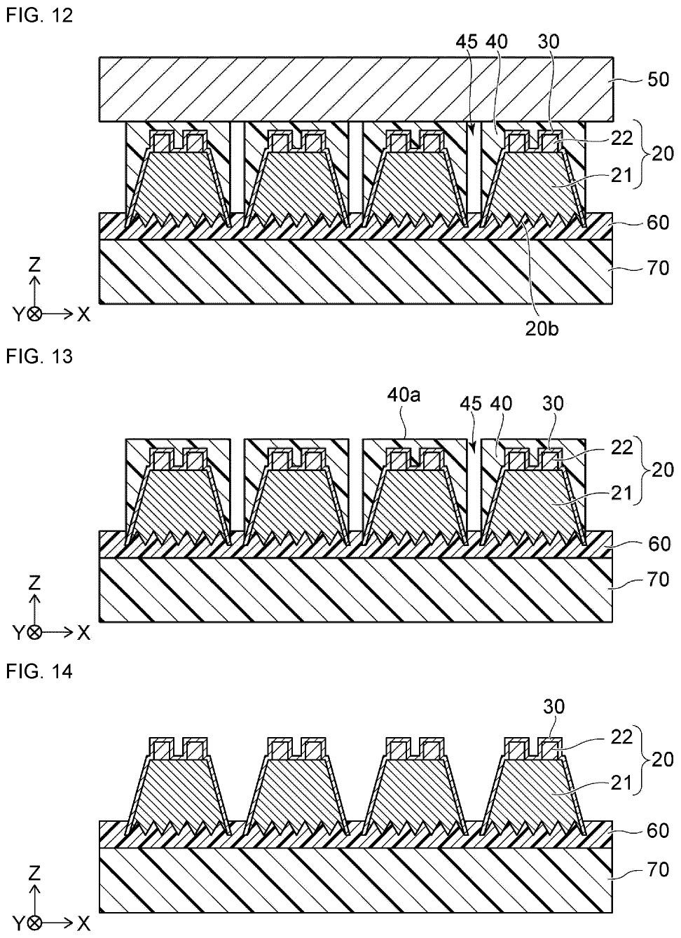

FIG. 8, FIG. 9, and FIG. 12 are cross-sectional views showing a fourth step of the method of manufacturing a light emitting device according to the embodiment.

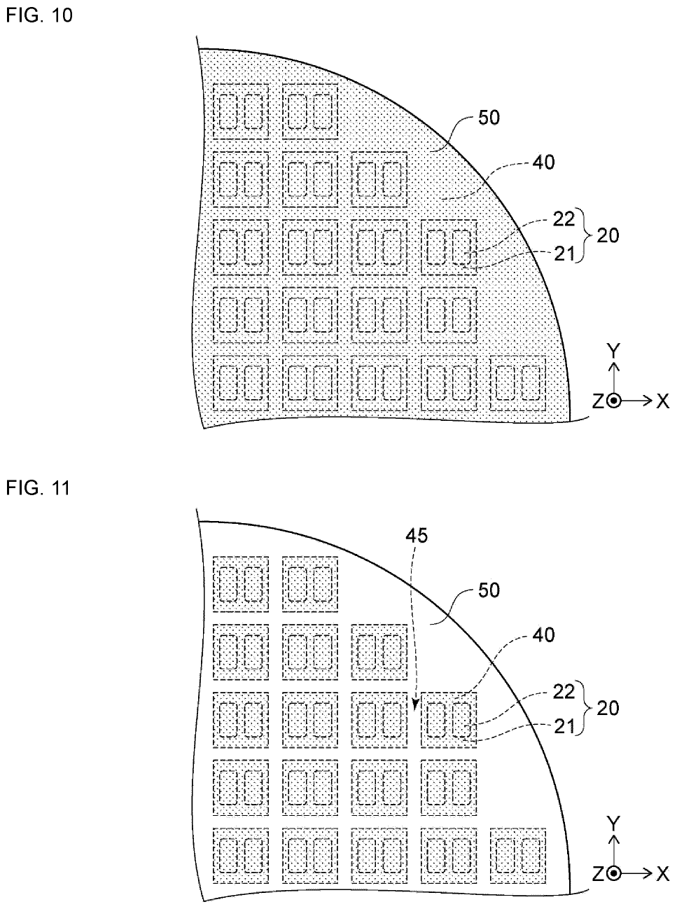

FIG. 10 and FIG. 11 are plan views showing the fourth step of the method of manufacturing a light emitting device according to the embodiment.

FIG. 13 is a cross-sectional view showing a fifth step of the method of manufacturing a light emitting device according to the embodiment.

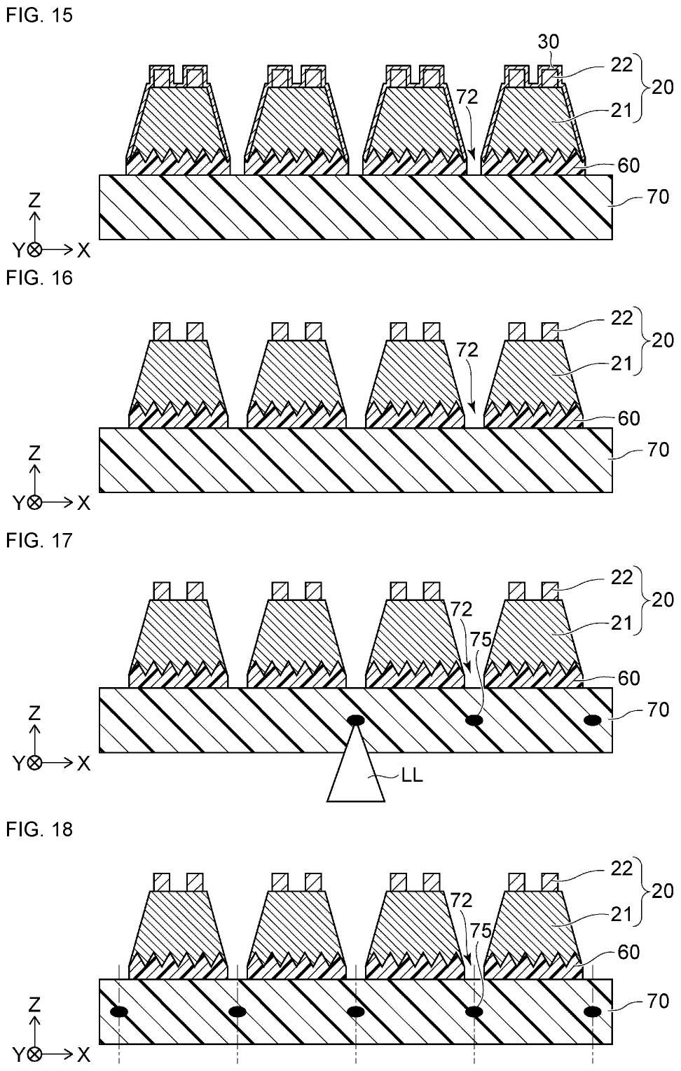

FIG. 14 and FIG. 15 are cross-sectional views showing a sixth step of the method of manufacturing a light emitting device according to the embodiment.

FIG. 16 is a cross-sectional view showing a seventh step of the method of manufacturing a light emitting device according to the embodiment.

FIG. 17 to FIG. 19 are cross-sectional views showing an eighth step of the method of manufacturing a light emitting device according to the embodiment.

FIG. 2 to FIG. 9 and FIG. 12 to FIG. 19 show cross sections taken along line II-II in FIG. 1.

As shown in FIG. 1 to FIG. 19, the method of manufacturing a light emitting device according to the embodiment comprises first to eighth steps. The first to eighth steps are conducted in the order of the first step, the second step, the third step, the fourth step, the fifth step, the sixth step, the seventh step, and the eighth step.

As shown in FIG. 1 to FIG. 4, in the first step, a structure 5 is provided. The structure 5 has a first substrate 10, a plurality of light emitting parts 20, a metal layer 30, and a protective member 40. The light emitting parts 20 are arranged on the upper surface 10a of the first substrate 10. The light emitting parts 20 are apart from one another. The metal layer 30 is disposed on the upper surface 10a side of the first substrate 10. The metal layer 30 covers at least the light emitting parts 20. The protective member 40 covers the metal layer 30. The structure 5 may be provided by purchasing.

As shown in FIG. 1 and FIG. 2, in the first step, the plurality of light emitting parts 20 are arranged on the upper surface 10a of the first substrate 10 so as to be apart from one another. The plurality of light emitting parts 20 are arranged on the upper surface 10a of the first substrate 10 by, for example, forming a single semiconductor part on the upper surface 10a of the first substrate 10, and then partially removing the semiconductor part to separate it into the plurality of light emitting parts 20. The semiconductor part can be formed by metalorganic chemical vapor deposition (MOCVD), for example. For example, in the state in which portions of the semiconductor part are covered by a photoresist, the portions of the semiconductor part that are not covered by the photoresist are removed. The removal of the semiconductor part can be performed by dry etching such as reactive ion etching (RIE), for example. The light emitting parts 20 are arranged such that the distance D between two adjacent light emitting parts 20 is in a range of 5 μm to 30 μm, for example. The light emitting parts 20 do not have to be apart from one another. For example, a plurality of light emitting parts 20 may be connected together via portions of the semiconductor parts thereof.

Each of the light emitting parts 20 has an upper surface 20a, a lower surface 20b, and a lateral surface 20c. The lateral surface 20c connects the upper surface 20a and the lower surface 20b. Each light emitting part 20 has a semiconductor layer structure 21 and electrodes 22. The upper surface of the semiconductor layer structure 21 and the upper surfaces of the electrodes 22 constitutes the upper surface 20a of the light emitting part 20. The lower surface of the semiconductor layer structure 21 constitutes the lower surface 20b of the light emitting part 20. The lateral surface of the semiconductor layer structure 21 constitutes the lateral surface 20c of the light emitting part 20. A single light emitting part 20 has, for example, a rectangular shape in a top view. When the top view shape of a light emitting part 20 is rectangular, the length of a side of the light emitting part 20 is, for example, in a range of 5 μm to 2000 μm.

A plurality of projections are formed on the upper surface 10a of the first substrate 10, for example. A plurality of recesses corresponding to the projections of the upper surface 10 of the first substrate 10 are formed on the lower surfaces 20b of the light emitting parts 20. The plurality of projections do not have to be formed on the upper surface 10a of the first substrate 10.

The first substrate 10 is a growth substrate for forming a semiconductor layer structure 21, for example. For example, the first substrate 10 includes at least one of sapphire, GaN, and silicon. The first substrate 10 is a sapphire substrate, for example. The first substrate 10 is 100 μm to 1000 μm in thickness, for example. The electrodes 22 include at least one of the metals: titanium (Ti), rhodium (Rh), gold (Au), platinum (Pt), ruthenium (Ru), and aluminum (Al), for example. The electrodes 22 may have a single layer structure, or a multilayer structure in which layers are stacked in the Z direction.

Each of the semiconductor layer structure 21 has a p-type semiconductor layer, an active layer, and an n-type semiconductor layer. The active layer is located between the p-type semiconductor layer and the n-type semiconductor layer. The p-type semiconductor layer, the active layer, and the n-type semiconductor layer are each made of a nitride semiconductor. In the present specification, “nitride semiconductors” include semiconductors of all compositions obtained by varying the composition ratio x and y within their ranges in the chemical formula InₓAl_{y}Ga_{1-x-y}N (0≤x≤1, 0≤y≤1, x+y≤1). Those further including a group V element in addition to N (nitrogen) and/or various elements added for controlling various physical properties such as conductivity type are also included in the “nitride semiconductors.”

The n-type semiconductor layer contains Si (silicon) as an n-type impurity, for example. The p-type semiconductor layer contains Mg (magnesium) as a p-type impurity, for example. The active layer is an emission layer that emits light, and has an MQW (multiple quantum well) structure that includes multiple barrier layers and multiple well layers, for example. The peak wavelength of the light emitted by the active layer is, for example, 210 nm to 580 nm.

As shown in FIG. 3, in the first step, a metal layer 30 is disposed on the upper surface 10a side of the first substrate 10 next. The metal layer 30 covers at least the light emitting parts 20. The metal layer 30 covers at least the upper surfaces 20a and the lateral surfaces 20c of the light emitting parts 20. The metal layer 30 is formed along the upper surfaces 20a and the lateral surfaces 20c of the light emitting parts 20, for example. In the example shown in FIG. 3, the metal layer 30 does not cover the upper surface 10a of the first substrate 10. The metal layer 30 may cover the upper surface 10a of the first substrate 10. The metal layer 30 can be formed by vapor deposition or sputtering, for example. For example, in the state in which portions of the upper surface 10a of the first substrate 10 are covered with a photoresist, a metal layer 30 is formed in the portions not covered by the photoresist. Accordingly, a metal layer 30 that covers the light emitting parts 20 without covering the upper surface 10a of the first substrate 10 can be formed. The metal layer 30 contains Cr (chromium), for example. A thickness of the metal layer 30 is in a range of 0.01 μm to 1 μm.

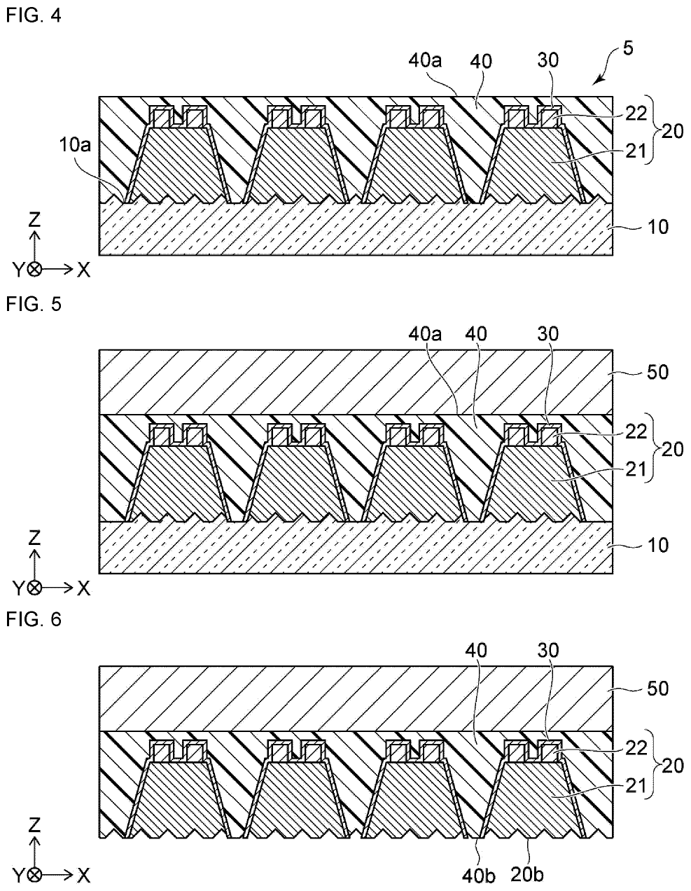

As shown in FIG. 4, in the first step, subsequently, a protective member 40 is disposed on the upper surface 10a side of the first substrate 10. The protective member 40 covers at least the metal layer 30. Portions of the protective member 40 are located between adjacent ones of the light emitting parts 20. In the example shown in FIG. 4, the protective member 40 covers the upper surface 10a of the first substrate 10. The protective member 40 does not have to cover the upper surface 10a of the first substrate 10. The protective member 40 is formed, for example, by being disposed to cover the light emitting parts 20 arranged on the upper surface 10a of the first substrate 10, and then flattening its surface opposite to a surface thereof at the first substrate 10 side. The protective member 40 includes a photosensitive adhesive, for example. The protective member 40 may have a single layer structure or multilayer structure in which layers are stacked in the Z direction.

As shown in FIG. 5, in the second step, a second substrate 50 is bonded onto the protective member 40. In the example shown in FIG. 5, the second substrate 50 is bonded to the upper surface 40a of the protective member 40. The second substrate 50 and the protective member 40 are bonded, for example, by using an adhesive resin such as a polyimide resin. After removal of the first substrate 10, the second substrate 50 functions as a support substrate for supporting the light emitting parts 20, the metal layer 30, and the protective member 40. For example, the second substrate 50 includes at least either sapphire or glass. The second substrate 50 is a sapphire substrate, for example.

As shown in FIG. 6, in the third step, the lower surfaces 30b of the light emitting parts 20 are exposed by removing the first substrate 10. In the example shown in FIG. 6, the removal of the first substrate 10 exposes the lower surfaces 20b of the light emitting parts 20 and the lower surface 40b of the protective member 40. The first substrate 10 is removed by laser lift off (LLO), for example. Subsequent to removing the first substrate 10, the lower surfaces 20b of the light emitting parts 20 and the lower surface 40b of the protective member 40 still have the shapes that correspond to the projections of the upper surface 10a of the first substrate 10.

As shown in FIG. 7, in the third step, the lower surfaces 20b of the light emitting parts 20 may be flattened after removing the first substrate 10. In the example shown in FIG. 7, the lower surfaces 20b of the light emitting parts 20 and the lower surface 40b of the protective member 40 are flattened. The “flattening” as used herein is a process that reduces the surface roughness. In other words, the surface roughness of the lower surfaces 20b of the light emitting parts 20 after flattening is smaller than the surface roughness of the lower surfaces 20b of the light emitting parts 20 before flattening. The surfaces are flattened by chemical mechanical polishing (CMP), for example. In the third step, the lower surfaces 20b of the light emitting parts 20 and the lower surface 40b of the protective member 40 do not have to be flattened. In the case in which the light emitting parts 20 are not spaced apart, i.e., they are connected via portions of the semiconductor parts of them, the portions of the semiconductor part are removed during the flattening process that separates the light emitting parts 20 from one another.

As shown in FIG. 8, in the fourth step, the lower surfaces 20b of the light emitting parts 20 are roughened. In the example shown in FIG. 8, the lower surface 40b of the protective member 40 is not roughened when the lower surfaces 20b of the light emitting parts 20 are roughened. The “roughening” as used herein is a process of increasing surface roughness. In other words, the surface roughness of the lower surfaces 20b of the light emitting parts 20 after roughening is larger than the surface roughness of the lower surfaces 20b of the light emitting parts 20 before roughening. The lower surfaces 20b of the light emitting parts 20 are roughened, for example, by wet etching using a strong alkaline solution. Examples of strong alkaline solutions include tetramethylammonium hydroxide (TMAH). The lower surfaces 20b of the light emitting parts 20 are roughened before bonding a light transmissive member 70 via a bonding member 60. Because the protective member 40 has a low etch rate in a strong alkaline solution such as TMAH, the lower surface 40b of the protective member 40 is not easily roughened, and the lower surfaces 20b of the light emitting parts 20 are easily roughened. In the fourth step, the lower surfaces 20b of the light emitting parts 20 do not have to be roughened. In the case of not performing flattening in the third step where the recesses that correspond to the projections of the upper surface 10a of the first substrate 10 remain on the lower surfaces 20b of the light emitting parts 20, roughening can produce rough surfaces in the lower surfaces 20b of the light emitting parts 20 that include the recesses.

As shown in FIG. 9 to FIG. 11, in the fourth step, next, grooves 45 are formed in the protective member 40 by continuously removing the portions of the protective member 40 not overlapping the light emitting parts 20 in a plan view. In the example shown in FIG. 9, the grooves 45 reach the second substrate 50. The grooves 45 do not have to reach the second substrate 50. The removal of protective member 40 is conducted, for example, by dry etching using oxygen gas. FIG. 10 shows the state before forming the grooves 45, and FIG. 11 shows the state after forming the grooves 45. In FIG. 10 and FIG. 11, the regions where the protective member 40 is disposed are shown using dot hatching. In the example shown in FIG. 10 and FIG. 11, the grooves 45 are formed between adjacent light emitting parts 20, and a single protective member 40 is provided with respect to a single light emitting part 20. In the fourth step, grooves 45 do not have to be formed. For example, if no gas is generated when the bonding member 60 is hardened, the grooves 45 do not have to be formed.

As shown in FIG. 12, in the fourth step, a light transmissive member 70 is bonded to the lower surfaces 20b of the light emitting parts 20 via a bonding member 60 next. More specifically, a material of the bonding member 60 that has not been hardened is applied to the light transmissive member 70 to form a layer of the bonding member 60 in the state before hardening. Then, the lower surfaces 20b of the light emitting parts 20 are pushed against the bonding member 60 that has not been hardened, causing the lower portions of the light emitting parts 20 to sink into the layer of the bonding member 60 that has not been hardened. Subsequently, the bonding member 60 is hardened by heating the material while the lower surfaces 20b of the light emitting parts 20 are pushed against thereto, so that the light transmissive member 70 is bonded to the lower surfaces 20b of the light emitting parts 20. The material for use as the bonding member 60 includes polysilazanes. The number of Si—O bonds in the hardened bonding member 60 is greater than that before hardening. The thickness of the bonding member 60 is in a range of 4 μm to 6 μm, for example. The light transmissive member 70 includes at least either a resin or glass, for example. The light transmissive member 70 may include a phosphor. The phosphor includes, for example, at least one of the following phosphors: yttrium aluminum garnet-based phosphors (e.g., Y₃(Al,Ga)₅O₁₂:Ce), nitride based phosphors such as β-SiAlON based phosphors (e.g., (Si,Al)₃(O,N)₄:Eu), CASN based phosphors (e.g., CaAlSiN₃:Eu), and SCASN based phosphors (e.g., (Sr,Ca)AlSiN₃:Eu), and fluoride based phosphors such as KSF based phosphors (e.g., K₂SiF₆:Mn) and KSAF based phosphors (e.g., K₂(Si,Al)F₆:Mn). The light transmissive member 70 may be a sintered body of a phosphor. The thickness of the light transmissive member 70 is smaller than the thickness of the first substrate 10, for example. The thickness of the light transmissive member 70 is, for example, in a range of 50 μm to 200 μm.

As shown in FIG. 13, in the fifth step, the second substrate 50 is removed. In the example shown in FIG. 13, the upper surface 40a of the protective member 40 is exposed by removing the second substrate 50. The second substrate 50 is removed by laser lift off (LLO), for example.

As shown in FIG. 14, in the sixth step, the protective member 40 is removed using the metal layer 30 as a mask. The protective member 40 is removed by reactive ion etching using a fluorine-based gas, for example. The fluorine-based gas includes at least one of CF₄, CHF₃, C₄F₈ and SF₆, for example. The protective member 40 may be removed by using a chemical that can strip the protective member 40, for example.

As shown in FIG. 15, in the sixth step, next, exposed portions 72 exposing the light transmissive member 70 from the bonding member 60 are created by removing the portions of the bonding member 60 each located between adjacent ones of the light emitting parts 20 using the metal layer 30 as a mask. The bonding member 60 is removed by reactive ion etching using a fluorine-based gas, for example. The protective member 40 and the bonding member 60 may be removed collectively by reactive ion etching with a fluorine-based gas.

As shown in FIG. 16, in the seventh step, the metal layer 30 is removed. The metal layer 30 is removed by wet etching using an etchant that can etch the metal layer 30, for example. In the case of using a metal layer 30 containing chromium, for example, the metal layer 30 is removed by wet etching using an etchant containing nitric acid.

As shown in FIG. 17, in the eighth step, modified portions 75 are formed in the light transmissive member 70 by irradiating a laser beam LL on locations of the exposed portions 72. The modified portions 75 are formed at the positions that overlap the exposed portions 72 by irradiating a laser beam LL on locations of the exposed portions 72 each located between adjacent ones of the light emitting parts 20. The modified portions 75 are formed by transforming portions of the light transmissive member 70 by focusing the laser beam LL inside the light transmissive member 70, for example. For the laser beam LL, a pulsed laser source is used, for example. In the case of using a pulsed laser, the pulse width is set to in a range of 300 fsec to 10 psec, for example.

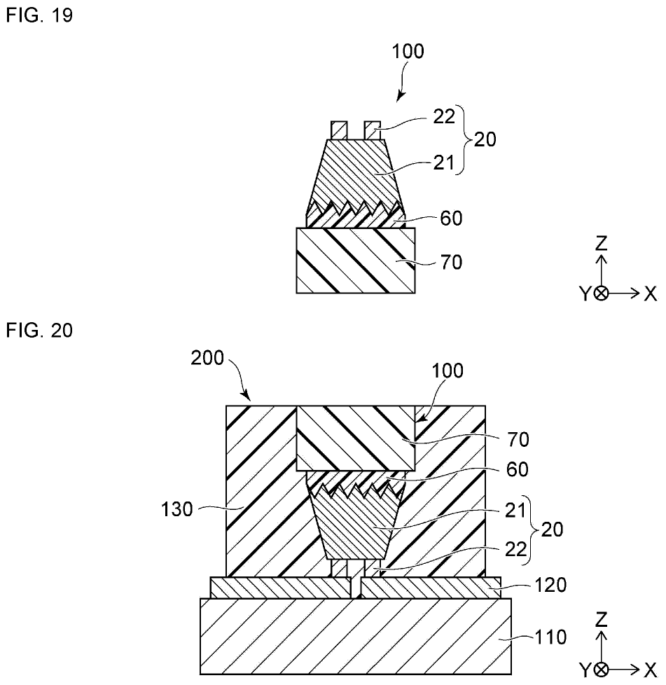

As shown in FIG. 18, in the eighth step, next, the light transmissive member 70 is divided into individual pieces by splitting the light transmissive member 70 at the locations of the modified portions 75. This produces a light emitting device 100 such as that shown in FIG. 19. The light transmissive member 70 is split by pressing a pressure member against the portions that overlap the modified portions 75, for example. The light transmissive member 70 is split along the modified portions 75 formed at the positions that overlap the exposed portions 72, resulting in a plurality of light emitting devices each having a light emitting part 20 and a light transmissive member 70. In the eighth step, the light transmissive member 70 may be divided into individual pieces by cutting the light transmissive member 70 at exposed portions 72 by blade dicing instead of forming modified portions 75.

The operational effects of a method of manufacturing a light emitting device according to an embodiment will be described below. In a manufacturing method in which a structure on which a plurality of light emitting parts are disposed is bonded to a light transmissive member and then the light transmissive member is divided into individual pieces, if a bonding member is arranged at locations where the light transmissive member is split, splitting failures are likely to occur. To reduce splitting failures, it is preferable to remove portions of the bonding member located at the splitting locations of the light transmissive member before splitting the light transmissive member. Depending on the bonding member, however, a mask for protecting the light emitting parts during the removal of the bonding member is required because it is difficult to secure the etching selectivity ratio of the bonding member with respect to the light emitting parts. At the same time, it is difficult to form a mask only on the light emitting parts immediately before splitting the light transmissive member because the light transmissive member is usually thin and easily breakable.

In contrast, in a method of manufacturing a light emitting device according to an embodiment of the present invention, the structure 5 including the metal layer 30 that covers the plurality of light emitting parts 20 is provided in the first step, and the light transmissive member 70 is bonded to the lower surfaces 20b of the light emitting parts 20 via the bonding member 60 in the fourth step. Then in the sixth step, exposed portions 72 in which the light transmissive member 70 is exposed from the bonding member 60 are created by removing the portions of the bonding member each located between adjacent ones of the light emitting parts 20 using the metal layer 30 as a mask. Then in the eighth step, the light transmissive member 70 is divided into individual pieces by splitting the light transmissive member 70 at the exposed portions 72. Accordingly, portions of the bonding member 60 at the splitting locations of the light transmissive member 70 can be removed using the metal layer 30 that has been formed on the light emitting parts as a mask before splitting the light transmissive member 70, thereby reducing splitting failures.

In the method of manufacturing a light emitting device according to one embodiment, moreover, modified portions 75 are formed in the light transmissive member 70 by irradiating a laser beam LL on the exposed portions 72 in the eighth step, followed by splitting the light transmissive member 70 at the positions of the modified portions 75 to divide the light transmissive member 70 into individual pieces. This can reduce the load applied to the light emitting parts 20 and the light transmissive member 70 as compared to the case of employing blade dicing, thereby improving the reliability of the light emitting devices.

In a method of manufacturing a light emitting device according to one embodiment, moreover, grooves 45 are formed in the protective member 40 in the fourth step by continuously removing the portions of the protective member 40 not overlapping the light emitting parts 20 in a plan view before bonding the light transmissive member 70 via the bonding member 60. This allows the gas generated while hardening the bonding member 60 to be evacuated out of the protective member 40 through the grooves 45 formed in the protective member 40. This can reduce occurrence of the bonding failures attributable to voids generated between the bonding member 60 and the light transmissive member 70 by the gas generated when the bonding member 60 is hardened.

In a method of manufacturing a light emitting device according to an embodiment, moreover, the lower surfaces 20b of the light emitting parts 20 are roughened before bonding a light transmissive member 70 via a bonding member 60 in the fourth step. This can enhance the adhesion between the lower surfaces 20b of the light emitting parts 20 and the bonding member 60. This can also facilitate the extraction of the light emitted by the light emitting parts 20 from the lower surfaces 20b of the light emitting parts 20, so that the light extraction efficiency of the light emitting devices 100 can be improved.

In a method of manufacturing a light emitting device according to an embodiment, furthermore, the lower surfaces 20b of the light emitting parts 20 are flattened after removing the first substrate 10 in the third step. This allows for removing the residues remaining after removing the first substrate 10, thereby increasing the efficiency in roughening the lower surfaces 20b of the light emitting parts 20 when the lower surfaces 20b of the light emitting parts 20 are subsequently roughened.

In a method of manufacturing a light emitting device according to an embodiment, moreover, a structure 5 having a metal layer 30 containing chromium is provided in the first step. This allows for the selective removal of the bonding member 60 while reducing the etching of the structure 5 when removing the bonding member 60.

In a method of manufacturing a light emitting device according to an embodiment, furthermore, a light transmissive member 70 is bonded via a bonding member 60 that is a hardened material containing a polysilazane. This can bond the light emitting parts 20 and the light transmissive member 70 using the bonding member 60 having a high content of inorganic components, thereby achieving a highly reliable light emitting device with reduced degradation of the bonding member 60 attributed to the light from the light emitting parts 20.

In a method of manufacturing a light emitting device according to an embodiment, furthermore, the portions of the bonding member 60 located between adjacent ones of the light emitting parts 20 are removed by reactive ion etching using a fluorine-based gas in the sixth step. This can improve the efficiency in removing the bonding member 60 even if it has a high content of inorganic components.

In a method of manufacturing a light emitting device according to an embodiment, moreover, a light transmissive member 70 containing a wavelength conversion material is bonded in the fourth step. This allows the light transmissive member 70 to convert the wavelength of a portion of the light from the light emitting parts 20 before the light exits the light emitting device 100.

In a method of manufacturing a light emitting device according to an embodiment, furthermore, a structure 5 in which light emitting parts 20 are arranged on the upper surface 10a of the first substrate 10 such that the distance D between adjacent light emitting parts 20 is 10 μm to 30 μm is provided in the first step. Setting the distance D to 10 μm or larger can increase the efficiency in removing the bonding member 60 located between adjacent light emitting parts 20. Setting the distance D to 30 μm or smaller can increase the number of light emitting parts 20 that can be arranged on the first substrate 10, thereby improving the production efficiency of the light emitting devices.

In a method of manufacturing a light emitting device according to an embodiment, moreover, a light transmissive member 70 is bonded to the lower surfaces 20b of the light emitting parts 20 via a bonding member 60 that is 4 μm to 6 μm in thickness in the fourth step. Setting the thickness of the bonding member 60 to 4 μm or larger can improve the bonding strength between the light emitting parts 20 and the light transmissive member 70. Setting the thickness of the bonding member 60 to 6 μm or smaller can increase the efficiency in removing the bonding member 60 in the sixth step.

In a method of manufacturing a light emitting device according to an embodiment, furthermore, a structure 5 in which light emitting parts 20 are covered by a metal layer 30 that is 0.01 μm to 1 μm in thickness is provided in the first step. Setting the thickness of the metal layer 30 to 0.01 μm or larger can reduce the etching of the light emitting parts 20 further when removing the bonding member 60 by using the metal layer 30 as a mask in the sixth step. Setting the thickness of the metal layer 30 to 1 μm or smaller can facilitate the removal of the metal layer 30 in the seventh step.

### Light Source

FIG. 20 is a cross-sectional view of a light source according to an embodiment.

As shown in FIG. 20, a light source 200 according to the embodiment includes a light emitting device 100, a mounting substrate 110, a conductive member 120, and a light reflecting member 130.

The mounting substrate 110 is located under the light source 200. The mounting substrate 110, for example, includes at least one of aluminum nitride and glass epoxy resin.

The conductive member 120 is disposed on the mounting substrate 110. The conductive member 120 includes at least one of Ti (titanium), Cu (copper), Ni (nickel), Pd (palladium), and Au (gold), for example.

The light emitting device 100 is disposed on the conductive member 120. The light emitting device 100 is disposed on the conductive member 120 with its electrodes 22 facing down. The light emitting device 100 is electrically connected to the conductive member 120 via the electrodes 22.

The light reflecting member 130 is disposed around the light emitting device 100 on the mounting substrate 110. The light reflecting member 130 includes a resin and a light reflecting material, for example. The resin includes at least one of silicone, epoxy, and acrylic resins, for example. The light reflecting material includes at least one of titanium oxide, aluminum oxide, and silicon oxide.

As described above, an embodiment of the invention can provide a method of manufacturing a light emitting device that can reduce splitting failures.

The embodiments described above are examples that give shape to the present invention, but the invention is not limited to these embodiments. For example, configurations and methods achieved by adding, deleting, or modifying certain elements or steps in any of the embodiments described above are also encompassed by the present invention. The embodiments described above may be implemented in combination.

What is claimed is:

1. A method of manufacturing a light emitting device, the method comprising:
providing a structure comprising:
a first substrate,
a plurality of light emitting parts arranged apart from one another on an upper surface of the first substrate,
a metal layer disposed on an upper surface side of the first substrate and covering at least the light emitting parts, and
a protective member covering the metal layer;
bonding a second substrate to the protective member;
exposing the lower surfaces of the light emitting parts by removing the first substrate;
bonding a light transmissive member to the lower surfaces of the light emitting parts via a bonding member;
removing the second substrate;
creating exposed portions of the light transmissive member exposed from the bonding member by, using the metal layer as a mask, removing portions of the bonding member located between adjacent ones of the light emitting parts, and removing the protective member;
removing the metal layer; and
dividing the light transmissive member into individual pieces by splitting the light transmissive member at the exposed portions.

2. The method of manufacturing a light emitting device according to claim 1, wherein, in the step of dividing the light transmissive member into the individual pieces, the light transmissive member is divided into individual pieces by forming modified portions in the light transmissive member by irradiating a laser beam on positions of the exposed portions, and splitting the light transmissive member at the modified portions.

3. The method of manufacturing a light emitting device according to claim 1, comprising, before bonding the light transmissive member to the lower surfaces of the light emitting parts via the bonding member, forming grooves in the protective member by continuously removing the portions of the protective member that do not overlap the light emitting parts in a plan view.

4. The method of manufacturing a light emitting device according to claim 2, comprising, before bonding the light transmissive member to the lower surfaces of the light emitting parts via the bonding member, forming grooves in the protective member by continuously removing the portions of the protective member that do not overlap the light emitting parts in a plan view.

5. The method of manufacturing a light emitting device according to claim 1, wherein the lower surfaces of the light emitting parts are roughened before bonding the light transmissive member via the bonding member in the step of bonding the light transmissive member to the lower surfaces of the light emitting parts.

6. The method of manufacturing a light emitting device according to claim 2, comprising, before bonding the light transmissive member to the lower surfaces of the light emitting parts via the bonding member, roughening the lower surfaces of the light emitting parts.

7. The method of manufacturing a light emitting device according to claim 1, comprising, after removing the first substrate, flattening the lower surfaces of the light emitting parts.

8. The method of manufacturing a light emitting device according to claim 2, comprising, after removing the first substrate, flattening the lower surfaces of the light emitting parts.

9. The method of manufacturing a light emitting device according to claim 1, wherein the metal layer contains chromium.

10. The method of manufacturing a light emitting device according to claim 2, wherein the metal layer contains chromium.

11. The method of manufacturing a light emitting device according to claim 3, wherein the metal layer contains chromium.

12. The method of manufacturing a light emitting device according to claim 1, wherein:
the bonding member contains a polysilazane, and
in the step of bonding the light transmissive member to the lower surfaces of the light emitting parts, the light transmissive member is bonded via the bonding member by hardening the bonding member.

13. The method of manufacturing a light emitting device according to claim 2, wherein:
the bonding member contains a polysilazane, and
in the step of bonding the light transmissive member to the lower surfaces of the light emitting parts, the light transmissive member is bonded via the bonding member by hardening the bonding member.

14. The method of manufacturing a light emitting device according to claim 3, wherein:
the bonding member contains a polysilazane, and
in the step of bonding the light transmissive member to the lower surfaces of the light emitting parts, the light transmissive member is bonded via the bonding member by hardening the bonding member.

15. The method of manufacturing a light emitting device according to claim 12, wherein, in the step of creating the exposed portions of the light transmissive member, the portions of the bonding member each located between adjacent ones of the light emitting parts are removed by reactive ion etching using a fluorine-based gas.

16. The method of manufacturing a light emitting device according to claim 1, wherein the light transmissive member contains a wavelength conversion material.

17. The method of manufacturing a light emitting device according to claim 1, wherein, in the step of providing the structure, the light emitting parts are arranged on the upper surface of the first substrate such that the distance between adjacent ones of the light emitting parts is in a range of 5 μm to 30 μm.

18. The method of manufacturing a light emitting device according to claim 1, wherein, in the step of bonding the light transmissive member to the lower surfaces of the light emitting parts, the bonding member has a thickness in a range of 4 μm to 6 μm.

19. The method of manufacturing a light emitting device according to claim 1, wherein, in the step of providing the structure, the metal layer has a thickness in a range of 0.01 μm to 1 μm.
